(19) United States
(12) Patent Application Publication
(10) Pub. No.: US 2026/0299369 A1
(43) Pub. Date: Oct. 1, 2026

(54) ELECTRO-ABSORPTION MODULATOR AND OPTICAL MODULATOR INTEGRATED LASER DEVICE

(71) Applicant: SUMITOMO ELECTRIC DEVICE INNOVATIONS, INC., Yokohama-shi (JP)

(72) Inventor: Kyohei MAEKAWA, Kanagawa (JP)

(73) Assignee: SUMITOMO ELECTRIC DEVICE INNOVATIONS, INC., Yokohama-shi (JP)

(21) Appl. No.: 19/578,286

(22) Filed: Mar. 25, 2026

(30) Foreign Application Priority Data
Mar. 27, 2025 (JP) 2025-054172
Dec. 3, 2025 (JP) 2025-227148

(51) Int. Cl. G02F 1/17; H01S 5/026

(52) U.S. Cl. CPC G02F 1/17; H01S 5/0265

(57) ABSTRACT

An electro-absorption modulator, comprising: a semi-insulating or insulating substrate; a first cladding layer of a first conductivity type provided on the substrate; a light absorption layer provided on the first cladding layer; a second cladding layer of a second conductivity type provided on the light absorption layer; and a contact layer of the first conductivity type including a part of the first cladding layer or provided between the substrate and the first cladding layer, wherein the first cladding layer, the light absorption layer, and the second cladding layer form a mesa structure extending in an optical waveguide direction, the contact layer includes: a first region including a region located between the mesa structure and the substrate; and a second region exposed from the first cladding layer for electrical connection, and the contact layer is partially removed on the substrate.

### CROSS REFERENCE TO RELATED APPLICATIONS

Priority is claimed on Japanese Patent Application No. 2025-054172, filed on Mar. 27, 2025, and Japanese Patent Application No. 2025-227148, filed on Dec. 3, 2025, the entire contents of each of which are incorporated herein by reference.

### TECHNICAL FIELD

The present disclosure relates to an electro-absorption modulator and an optical modulator integrated laser device.

### BACKGROUND

Japanese Unexamined Patent Publication No. 2002-277840 discloses an electro-absorption modulator. The electro-absorption modulator includes an n-electrode and a p-electrode. A non-inverted signal and an inverted signal, which form a differential signal, are input to the n-electrode and the p-electrode, respectively.

### SUMMARY

An electro-absorption modulator according to an aspect of the present disclosure includes a substrate, a first cladding layer, a light absorption layer, a second cladding layer, and a contact layer of the first conductivity type. The substrate has a semi-insulating or insulating property. The light absorption layer is provided on the first cladding layer. The second cladding layer is provided on the light absorption layer. The contact layer includes a part of the first cladding layer, or is provided between the substrate and the first cladding layer. The first cladding layer, the light absorption layer, and the second cladding layer form a mesa structure extending in the optical waveguide direction. The contact layer includes a first region including a region located between the mesa structure and the substrate and a second region exposed from the first cladding layer for electrical connection. The contact layer is partially removed on the substrate. The first region and the second region are interposed between regions where the contact layer has been removed.

### BRIEF DESCRIPTION OF THE DRAWINGS

FIG. 1 is a plan view showing an optical modulator integrated laser device according to an embodiment of the present disclosure.

FIG. 2 is a drawing schematically showing a cross section taken along the line II-II in FIG. 1.

FIG. 3 is a drawing schematically showing a cross section taken along the line III-III in FIG. 1.

FIG. 4 is a drawing schematically showing a cross section taken along the line IV-IV in FIG. 1.

FIG. 5 is a drawing schematically showing a cross section taken along the line V-V in FIG. 1.

FIG. 6 is a drawing showing parts of FIGS. 2, 3, 4, and 5 in an enlarged manner.

FIG. 7 is a drawing showing a further enlarged view of a part of FIG. 6.

FIG. 8 is a drawing schematically showing a cross section taken along the line VIII-VIII in FIG. 1.

FIG. 9 is a drawing showing a step of growing a contact layer, an etching stop layer, a first cladding layer, a light absorption layer, and a second cladding layer on a substrate.

FIG. 10 is a drawing showing a step of removing an insulating film on a mesa structure and in a region around the mesa structure.

FIG. 11 is a graph showing the frequency characteristics of S parameters of the optical modulator.

FIG. 12 is a graph showing the frequency characteristics of S parameters of the optical modulator.

FIG. 13 is a plan view showing an optical modulator integrated laser device according to a first Modification.

FIG. 14 is a circuit diagram showing a case where a first region reaches a light emission end surface.

FIG. 15 is a plan view showing a configuration in which the first region does not reach the light emission end surface.

FIG. 16 is a circuit diagram showing a case where the first region does not reach the light emission end surface.

FIG. 17 is a plan view showing an optical modulator integrated laser device according to a second Modification.

FIG. 18 is a plan view showing an optical modulator integrated laser device according to a third Modification.

FIG. 19 is a plan view showing an optical modulator integrated laser device according to a fourth Modification.

FIG. 20 is a plan view showing an optical modulator integrated laser device according to a fifth Modification.

FIG. 21 is a plan view showing an optical modulator integrated laser device according to a sixth Modification.

FIG. 22 is a drawing showing another structural example of a first region where a contact layer has been removed.

FIG. 23 is a drawing showing another structural example of a first region where a contact layer has been removed.

FIG. 24 is a drawing showing a step of depositing an embedding region in an etched region.

FIG. 25 is a drawing showing a step of depositing an embedding region in an etched region.

FIG. 26 is a drawing showing still another structural example of a first region where a contact layer has been removed.

FIG. 27 is a drawing showing a cross section of a laser section not including a first region.

### DETAILED DESCRIPTION

When performing differential driving of an electro-absorption modulator, electrical connection is facilitated by providing an electrode pad connected to an n-electrode and an electrode pad connected to a p-electrode on the upper surface of the electro-absorption modulator. For this purpose, for example, it is conceivable to form a lower cladding layer, a light absorption layer, and an upper cladding layer on an insulating or semi-insulating substrate and provide a contact layer between the lower cladding layer and the substrate. In one example, the contact layer and the lower cladding layer are of n-type, and the upper cladding layer is of p-type. In another example, the contact layer and the lower cladding layer are of p-type, and the upper cladding layer is of n-type. Then, for electrical connection, the contact layer is exposed from the lower cladding layer. A non-inverted signal and an inverted signal, which form a differential signal, are input to the contact layer and the upper cladding layer, respectively.

However, in certain structures, the electro-absorption modulator is mounted on a base having a reference potential (ground potential). In such a structure, parasitic capacitance is generated between the contact layer and the base. Due to this parasitic capacitance, there is a risk that the high-frequency characteristics of the electro-absorption modulator may be degraded.

It is an object of the present disclosure to provide an electro-absorption modulator and an optical modulator integrated laser device that can improve high-frequency characteristics by reducing parasitic capacitance.

### DESCRIPTION OF EMBODIMENTS OF THE PRESENT DISCLOSURE

First, the contents of embodiments of the present disclosure will be listed and described.
(1) An electro-absorption modulator according to an embodiment of the present disclosure includes a substrate, a first cladding layer, a light absorption layer, a second cladding layer, and a contact layer of the first conductivity type. The substrate has a semi-insulating or insulating property. The light absorption layer is provided on the first cladding layer. The second cladding layer is provided on the light absorption layer. The contact layer includes a part of the first cladding layer, or is provided between the substrate and the first cladding layer. The first cladding layer, the light absorption layer, and the second cladding layer form a mesa structure extending in the optical waveguide direction. The contact layer includes a first region including a region located between the mesa structure and the substrate and a second region exposed from the first cladding layer for electrical connection. The contact layer is partially removed on the substrate. The first region and the second region are interposed between regions where the contact layer has been removed.
In the electro-absorption modulator according to (1) above, the contact layer is partially removed on the substrate, and the first region between the mesa structure and the substrate and the second region exposed from the first cladding layer for electrical connection are interposed between the regions where the contact layer has been removed. In this manner, by removing the contact layer around the first region and the second region, parasitic capacitance generated between the first region and the second region of the contact layer and a base can be reduced, thereby improving the high-frequency characteristics of the electro-absorption modulator.
(2) The electro-absorption modulator according to (1) above may further include a first electrode pad electrically connected to the contact layer and a second electrode pad electrically connected to the second cladding layer. The contact layer may further include a third region located between the first electrode pad and the substrate and a fourth region located between the second electrode pad and the substrate. The third region and the fourth region may be electrically isolated from the first region and the second region by the regions where the contact layer has been removed. The first electrode pad and the second electrode pad are provided, for example, above the second cladding layer with an insulating film interposed therebetween in order to maintain the height. In such a case, the third region and the fourth region of the contact layer located below the first electrode pad and the second electrode pad are not removed but remain. By electrically isolating the third region and the fourth region from the first region and the second region using the region where the contact layer has been removed, parasitic capacitance generated between the first region and the second region of the contact layer and the base can be reduced, thereby improving the high-frequency characteristics of the electro-absorption modulator.
(3) In the electro-absorption modulator according to (2) above, in addition to the first region, the second region, the third region, and the fourth region, a region where the contact layer has not been removed may be present. In this case, the time required to remove the contact layer can be shortened by reducing the area of the region where the contact layer is to be removed.
(4) In the electro-absorption modulator according to (1) above, the contact layer may be removed in all regions excluding the first region and the second region. In this case, parasitic capacitance generated between the first region and the second region of the contact layer and the base can be further reduced, thereby further improving the high-frequency characteristics of the electro-absorption modulator.
(5) In the electro-absorption modulator according to any one of (1) to (4) above, the regions where the contact layer has been removed may reach the light emission end surface. In this case, the first region is interposed between the regions where the contact layer has been removed, up to the light emission end surface. As a result, since the parasitic capacitance generated between the first region of the contact layer and the base is further reduced, it is possible to further improve the high-frequency characteristics of the electro-absorption modulator. In addition, when a laser section is provided as in (8) below, it is possible to increase the isolation resistance between the electro-absorption modulator and the laser section by increasing the resistance (tip side isolation resistance) for isolating the electro-absorption modulator from the tip side region.
(6) The electro-absorption modulator according to any one of (1) to (5) above may further include a semi-insulating or insulating embedding region that embeds both sides of the mesa structure. The regions where the contact layer has been removed are regions where a recess penetrating the embedding region and the contact layer is formed. In this case, partial removal of the contact layer on the substrate can be easily performed.
(7) In the electro-absorption modulator according to (6) above, the first region may include a first portion including a light emission end surface and a second portion located on a side opposite to the light emission end surface with respect to the first portion. A width of the first portion in a direction perpendicular to the optical waveguide direction may be greater than a width of the second portion in the direction perpendicular to the optical waveguide direction. In this case, since the width of the portion interposed between the recesses increases at the light emission end surface, the mechanical strength of the portion interposed between the recesses increases, making it easier to cleave the light emission end surface.
(8) The electro-absorption modulator according to any one of (1) to (7) above may include a first optical modulator and a second optical modulator.
(9) An optical modulator integrated laser device according to an embodiment of the present disclosure includes an optical modulator section that is the electro-absorption modulator according to any one of (1) to (8) above, and a laser section that is provided on the substrate and outputs laser light. The optical modulator section receives the laser light from the laser section. According to this optical modulator integrated laser device, since the electro-absorption modulator according to any one of (1) to (8) above is included, the parasitic capacitance generated between the contact layer and the base can be reduced, thereby improving the high-frequency characteristics.
(10) In the optical modulator integrated laser device according to (9) above, the contact layer may be partially removed on the substrate in the laser section. In this case, parasitic capacitance generated between the contact layer and the base can be further reduced, thereby further improving the high-frequency characteristics of the optical modulator.
(11) The optical modulator integrated laser device according to (9) above may further include a semiconductor optical amplifier provided on a light emission end surface side of the optical modulator section. The semiconductor optical amplifier may receive the laser light after modulation from the optical modulator section, amplify and output the modulated laser light.
(12) In the optical modulator integrated laser device according to (11) above, the semiconductor optical amplifier may be provided on the substrate. In this case, the optical modulator integrated laser device including the semiconductor optical amplifier can be made smaller.

### DETAILS OF EMBODIMENTS OF THE PRESENT DISCLOSURE

Specific examples of the present disclosure will be described below with reference to the accompanying drawings. The present disclosure is not limited to these examples, but is defined by the claims, and is intended to include all modifications within the meaning and scope equivalent to the claims. In the following description, the same elements will be denoted by the same reference numerals in the description of the drawings, and repeated description thereof will be omitted.

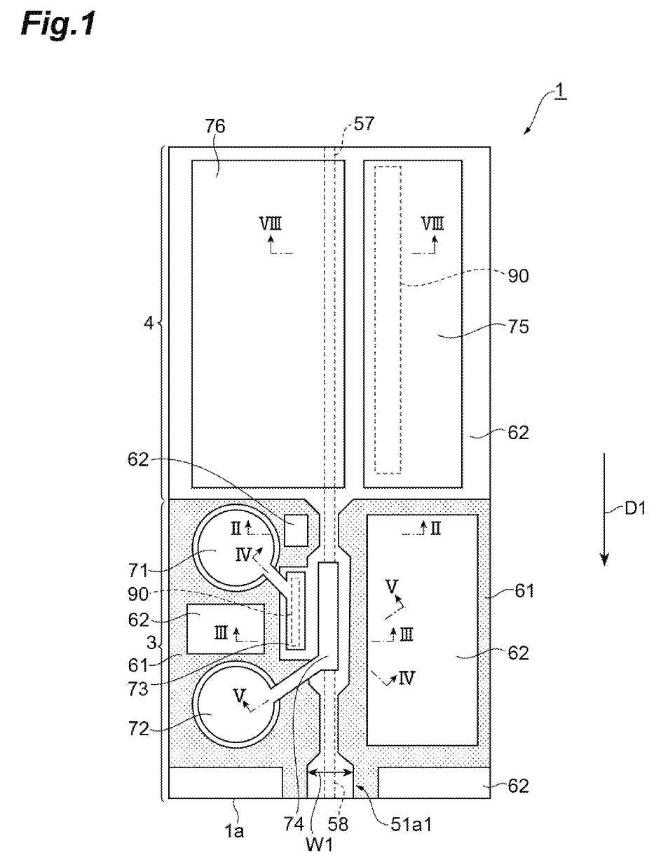

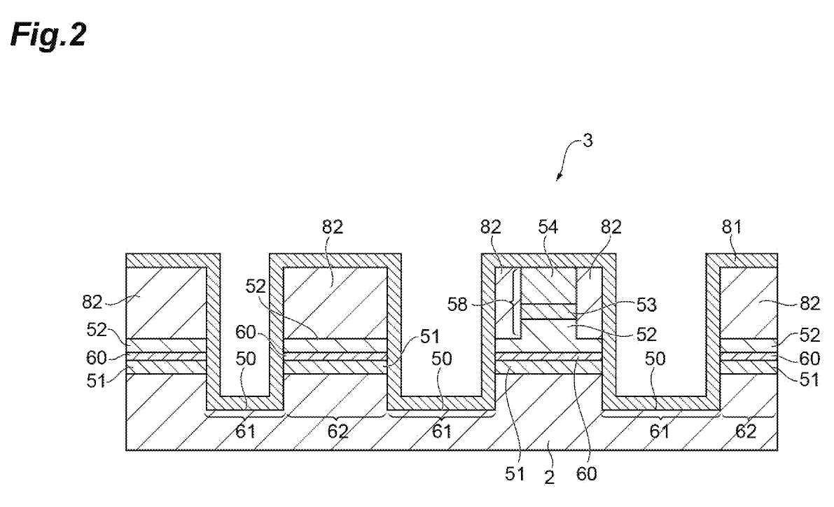

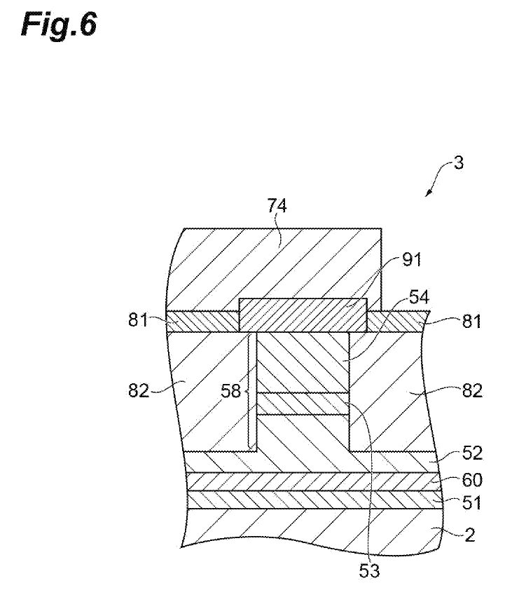

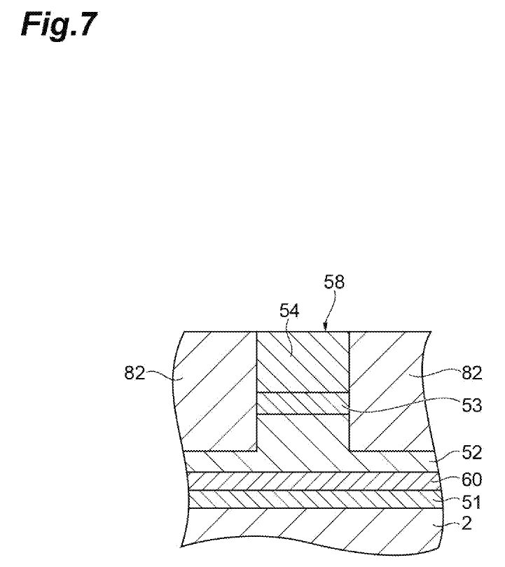

FIG. 1 is a plan view showing an optical modulator integrated laser device 1 according to an embodiment of the present disclosure. FIGS. 2, 3, 4, and 5 are drawings schematically showing cross sections taken along the lines II-II, III-III, IV-IV, and V-V in FIG. 1, respectively. FIG. 6 is a drawing showing parts of FIGS. 2, 3, 4, and 5 in an enlarged manner. FIG. 7 is a drawing showing a further enlarged view of a part of FIG. 6.

The optical modulator integrated laser device 1 according to the present embodiment includes an optical modulator 3 and a laser section 4. The optical modulator 3 and the laser section 4 are monolithically provided on a common substrate 2. The optical modulator 3 and the laser section 4 are adjacent to each other along an optical waveguide direction D1 on the substrate 2. The laser section 4 outputs laser light. The optical modulator 3 receives the laser light from the laser section 4.

The optical modulator 3 is an electro-absorption modulator, and includes the substrate 2, a contact layer 51, a first cladding layer 52, a light absorption layer 53, and a second cladding layer 54. The substrate 2 has a semi-insulating or insulating property. The substrate 2 contains, for example, a III-V compound semiconductor, and is an InP substrate in one example.

The contact layer 51 is an electrode-connection semiconductor layer in the present disclosure. The contact layer 51 is provided on the substrate 2 and has a first conductivity type. The first conductivity type is, for example, n-type. The contact layer 51 contains a semiconductor that is lattice-matched to the substrate 2, and is an n⁺-type InP layer in one example. In the present embodiment, the contact layer 51 is provided on the substrate 2 and is in contact with the substrate 2. The thickness of the contact layer 51 is smaller than the thickness of the first cladding layer 52. The thickness of the contact layer 51 is 100 nm or more and 1000 nm or less, and is 400 nm in one example. The impurity concentration of the contact layer 51 is higher than the impurity concentration of the first cladding layer 52. The impurity concentration of the contact layer 51 is 1 × 10¹⁸ cm⁻³ or more and 2 × 10¹⁹ cm⁻³ or less, and is 8 × 10¹⁸ cm⁻³ in one example.

The first cladding layer 52 is provided on the contact layer 51 and has the first conductivity type. The first cladding layer 52 contains a semiconductor that is lattice-matched to the contact layer 51, and is an n-type InP layer in one example. In the present embodiment, the first cladding layer 52 is provided on the contact layer 51 and is in contact with the contact layer 51. The thickness of the first cladding layer 52 is 0.5 μm or more and 2 μm or less, and is 1.2 μm in one example. The impurity concentration of the first cladding layer 52 is 1 × 10¹⁷ cm⁻³ or more and 2 × 10¹⁸ cm⁻³ or less, and is 5 × 10¹⁷ cm⁻³ in one example.

The light absorption layer 53 is provided on the first cladding layer 52. The band gap of the light absorption layer 53 is smaller than the band gap of the first cladding layer 52. The refractive index of the light absorption layer 53 is greater than the refractive index of the first cladding layer 52. The light absorption layer 53 contains a semiconductor that is lattice-matched to the first cladding layer 52. The light absorption layer 53 may have a multiple quantum well structure. In one example, the light absorption layer 53 is formed by stacking InGaAsP layers or InGaAlAs layers having different compositions. In the present embodiment, the light absorption layer 53 is provided on the first cladding layer 52 and is in contact with the first cladding layer 52.

The second cladding layer 54 is provided on the light absorption layer 53 and has a second conductivity type. The second conductivity type is, for example, p-type. The second cladding layer 54 contains a semiconductor that is lattice-matched to the light absorption layer 53, and is a p-type InP layer in one example. In the present embodiment, the second cladding layer 54 is provided on the light absorption layer 53 and is in contact with the light absorption layer 53.

As shown in FIG. 6, the optical modulator 3 further includes an etching stop layer 60. The etching stop layer 60 is provided between the contact layer 51 and the first cladding layer 52. In one example, the etching stop layer 60 is in contact with the contact layer 51 and the first cladding layer 52. The etching stop layer 60 is used to stop etching, based on a difference in etching rate from the first cladding layer 52, when forming an ohmic electrode 90 in contact with the contact layer 51. The etching stop layer 60 has the first conductivity type. The etching stop layer 60 is, for example, an n-type InGaAsP layer.

The first cladding layer 52, the light absorption layer 53, and the second cladding layer 54 form a mesa structure 58 extending along the optical waveguide direction D1. The width of the mesa structure 58 in a lateral direction is, for example, 1.4 μm. A base end of the mesa structure 58 is present in the first cladding layer 52. Therefore, lower portions of the contact layer 51, the etching stop layer 60, and the first cladding layer 52 also extend outside the mesa structure 58 in plan view.

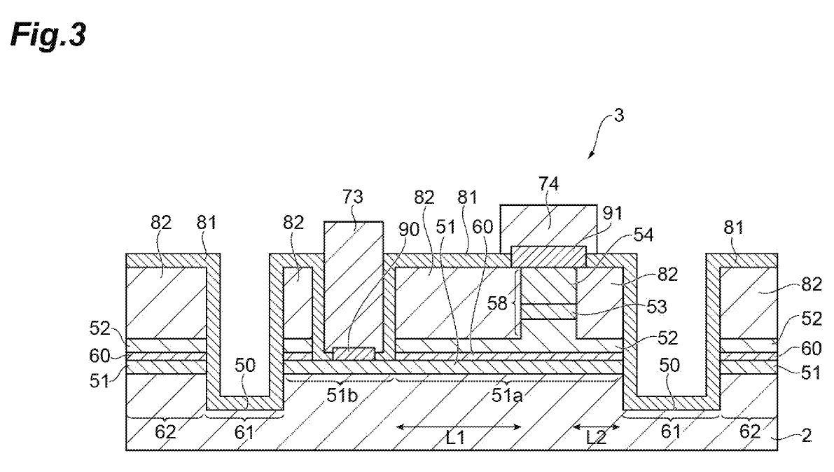

The contact layer 51 includes a first region 51a and a second region 51b. The first region 51a includes a region located between the mesa structure 58 and the substrate 2 and a peripheral region thereof. In plan view, distances L1 and L2 (see FIG. 3) between ends of the first region 51a and the mesa structure 58 in a direction perpendicular to the optical waveguide direction D1 and along an upper surface of the substrate 2 (hereinafter referred to as a lateral direction) are, for example, 3 μm or more and 20 μm or less, and are 10 μm in one example. The second region 51b is a region exposed from the first cladding layer 52 and the etching stop layer 60 for electrical connection with a wiring 73, which will be described later. The second region 51b is adjacent to the first region 51a.

The optical modulator 3 further includes an insulating film 81 and an embedding region 82. The embedding region 82 is provided on both sides of the mesa structure 58 to embed both side surfaces of the mesa structure 58. The embedding region 82 has an insulating or semi-insulating property. The embedding region 82 is, for example, a semi-insulating InP region. The material of the embedding region 82 may be the same as the material of the substrate 2, or may be different from the material of the substrate 2. The insulating film 81 is provided on the embedding region 82 to cover the embedding region 82. The insulating film 81 is, for example, a silicon compound film such as SiO₂ or SiN.

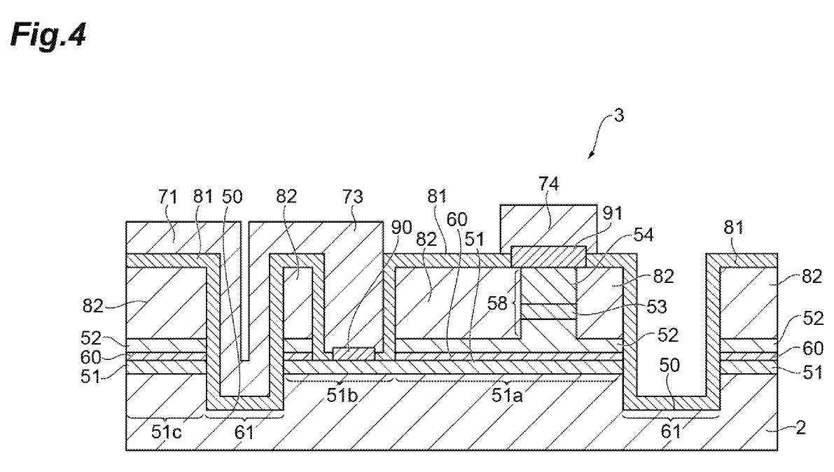

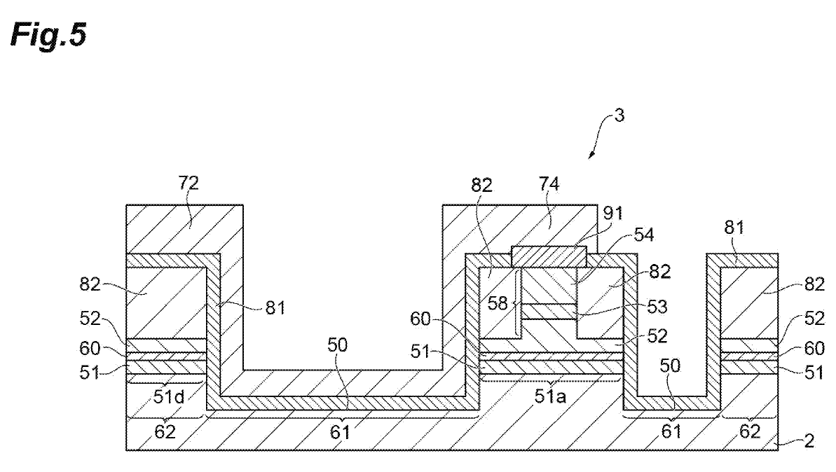

The optical modulator 3 includes a first electrode pad 71, a second electrode pad 72, a wiring 73, and a wiring 74. The first electrode pad 71, the second electrode pad 72, the wiring 73, and the wiring 74 are metal films, and are gold (Au) films in one example. As shown in FIGS. 4 and 5, the first electrode pad 71 and the second electrode pad 72 are provided above the embedding region 82 and on the insulating film 81. As shown in FIG. 1, the first electrode pad 71 and the second electrode pad 72 are arranged laterally with respect to the mesa structure 58. In addition, the first electrode pad 71 and the second electrode pad 72 are arranged side by side along the optical waveguide direction D1. The planar shapes of the first electrode pad 71 and the second electrode pad 72 are, for example, circular.

The wiring 73 electrically connects the first electrode pad 71 and the contact layer 51 to each other. The wiring 73 includes the ohmic electrode 90, which is a portion provided on the second region 51b of the contact layer 51 to make ohmic contact with the second region 51b, and a portion connected to the first electrode pad 71. Portions of the wiring 73 other than the portion in contact with the second region 51b are provided on the insulating film 81. The wiring 74 electrically connects the second electrode pad 72 and the second cladding layer 54 to each other. The wiring 74 includes an ohmic electrode 91, which is a portion provided on the second cladding layer 54 to make ohmic contact with the second cladding layer 54, and a portion connected to the second electrode pad 72. Portions of the wiring 74 other than the portion in contact with the second cladding layer 54 are provided on the insulating film 81.

The contact layer 51 further includes a third region 51c and a fourth region 51d. The third region 51c is a region located between the first electrode pad 71 and the substrate 2. The planar shape of the third region 51c is the same as that of the first electrode pad 71 (for example, circular). The fourth region 51d is a region located between the second electrode pad 72 and the substrate 2. The planar shape of the fourth region 51d is the same as that of the second electrode pad 72 (for example, circular).

A recess 50 is formed in the embedding region 82. The recess 50 penetrates the embedding region 82, the first cladding layer 52, the etching stop layer 60, and the contact layer 51. The recess 50 is formed to partially remove the contact layer 51 on the substrate 2. In FIG. 1, a region 61 where the contact layer 51 has been removed is indicated by stippling. That is, the region 61 is a region where the recess 50 is formed. As shown in FIG. 1, an integrated region formed by the first region 51a and the second region 51b is interposed between the regions 61 in the lateral direction. In the present embodiment, the region 61 reaches a light emission end surface 1a. As a result, the first region 51a is interposed between the regions 61 up to the light emission end surface 1a. The insulating film 81 is provided on the surface of the recess 50. The third region 51c and the fourth region 51d are electrically isolated from the first region 51a and the second region 51b by the region 61 where the contact layer 51 has been removed, that is, the recess 50.

In the optical modulator 3, the first region 51a includes a portion 51a1 (first portion, see FIG. 1) including the light emission end surface 1a and a remaining portion (second portion) located on a side opposite to the light emission end surface 1a with respect to the portion 51a1. Then, the width W1 of the portion 51a1 in the lateral direction is greater than the width of the remaining portion in the lateral direction.

On the substrate 2, in addition to the region 61, a region 62 is further present. The region 62 is a region where the contact layer 51 has not been removed, other than the first region 51a, the second region 51b, the third region 51c, and the fourth region 51d. No recess 50 is formed in the region 62. For this reason, the contact layer 51, the etching stop layer 60, the first cladding layer 52, and the embedding region 82 remain. The region 62 in the present embodiment has an island-like shape that is electrically isolated.

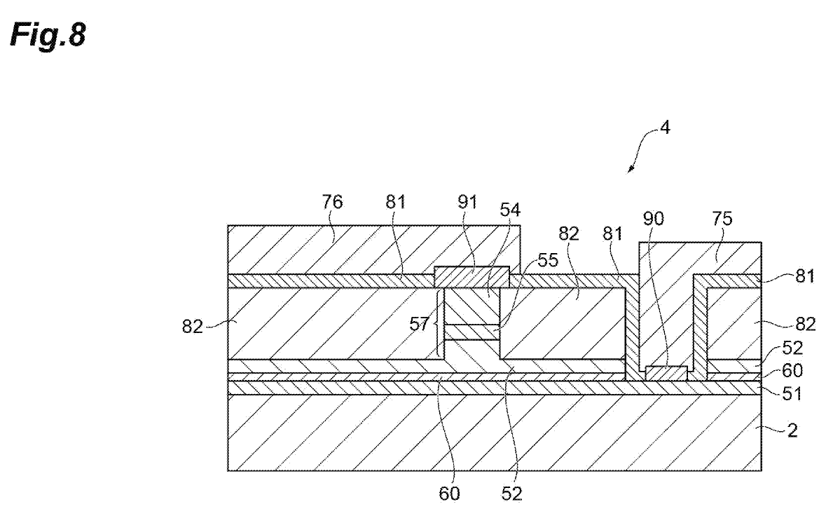

FIG. 8 is a drawing schematically showing a cross section taken along the line VIII-VIII in FIG. 1. The laser section 4 has the same configuration as the optical modulator 3 except for the following points. The laser section 4 has an active layer 55 instead of the light absorption layer 53 of the optical modulator 3. The first cladding layer 52, the active layer 55, and the second cladding layer 54 form a mesa structure 57 extending along the optical waveguide direction D1. The laser section 4 has an electrode pad 75 instead of the first electrode pad 71 and the wiring 73 of the optical modulator 3. The laser section 4 has an electrode pad 76 instead of the second electrode pad 72 and the wiring 74 of the optical modulator 3. The electrode pad 75 is provided above the embedding region 82 and on the insulating film 81, and extends to one side of the mesa structure 57. The electrode pad 75 includes the ohmic electrode 90 that makes ohmic contact with an exposed portion of the contact layer 51. The electrode pad 76 is provided above the embedding region 82 and on the insulating film 81, and extends to the other side of the mesa structure 57. The electrode pad 76 includes the ohmic electrode 91 that makes ohmic contact with an exposed portion of the second cladding layer 54. As shown in FIG. 1, in the present embodiment, the region 61 is not formed in the laser section 4.

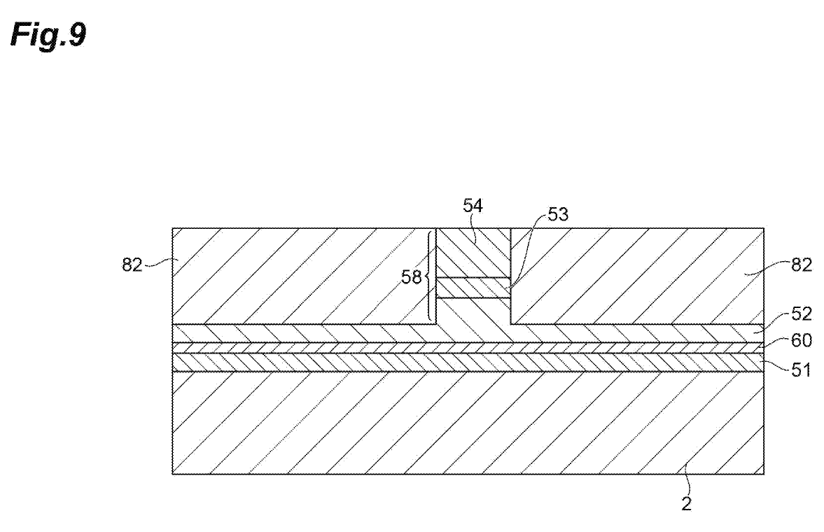

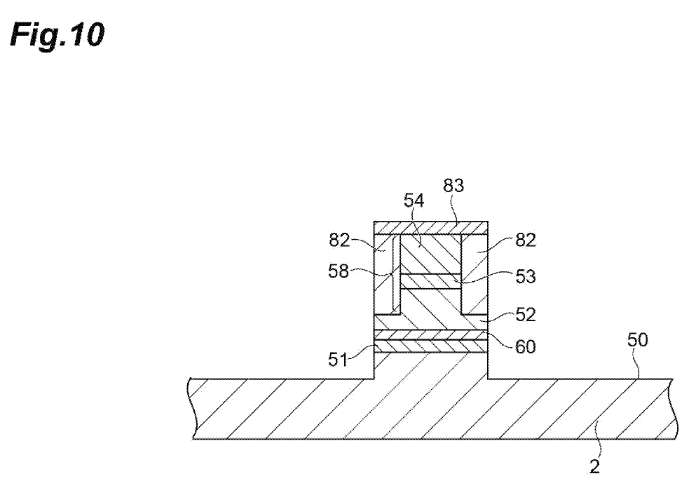

Next, a method for forming the region 61 of the optical modulator 3 will be described. First, as shown in FIG. 9, the contact layer 51, the etching stop layer 60, the first cladding layer 52, the light absorption layer 53, and the second cladding layer 54 are grown on the substrate 2. The mesa structure 58 is formed by etching (for example, dry etching). The embedding region 82 is deposited in a region on the substrate 2 excluding the mesa structure 58 to embed the mesa structure 58. Thereafter, as shown in FIG. 10, an etching mask 83 is formed on the mesa structure 58 and on the embedding region 82 therearound. A portion of the embedding region 82 exposed from the etching mask 83 and the first cladding layer 52, the etching stop layer 60, and the contact layer 51 therebelow are removed by etching (for example, dry etching) to expose the substrate 2. Through these steps, the region 61 (recess 50) is formed. Thereafter, the insulating film 81 (see FIGS. 2-6 and 8) is formed on the embedding region 82.

The effects obtained by the optical modulator integrated laser device 1 and the optical modulator 3 according to the present embodiment described above will be described. In the optical modulator 3 according to the present embodiment, the contact layer 51 is partially removed on the substrate 2, and the first region 51a between the mesa structure 58 and the substrate 2 and the second region 51b exposed from the first cladding layer 52 for electrical connection are interposed between the regions 61 where the contact layer 51 has been removed. In this manner, by removing the contact layer 51 around the first region 51a and the second region 51b, parasitic capacitance generated between the first region 51a and the second region 51b of the contact layer 51 and a conductive base on which the optical modulator integrated laser device 1 is mounted can be reduced, thereby improving the high-frequency characteristics of the optical modulator 3.

As in the present embodiment, the optical modulator 3 may further include the first electrode pad 71 electrically connected to the contact layer 51 and the second electrode pad 72 electrically connected to the second cladding layer 54. The contact layer 51 may further include the third region 51c located between the first electrode pad 71 and the substrate 2 and the fourth region 51d located between the second electrode pad 72 and the substrate 2. The third region 51c and the fourth region 51d may be electrically isolated from the first region 51a and the second region 51b by the region 61 where the contact layer 51 has been removed. The first electrode pad 71 and the second electrode pad 72 are provided, for example, above the embedding region 82 with an insulating film interposed therebetween in order to maintain the height. In such a case, the third region 51c and the fourth region 51d of the contact layer 51 located below the first electrode pad 71 and the second electrode pad 72 are not removed but remain. By electrically isolating such third region 51c and fourth region 51d from the first region 51a and the second region 51b by the region 61 where the contact layer 51 has been removed, parasitic capacitance generated between the first region 51a and the second region 51b of the contact layer 51 and the base can be reduced, thereby improving the high-frequency characteristics of the optical modulator 3.

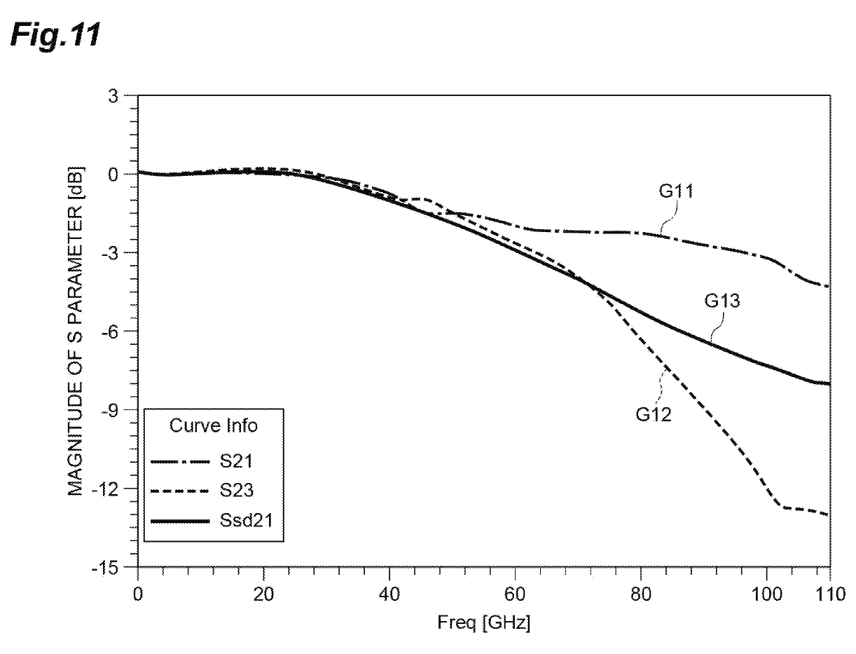

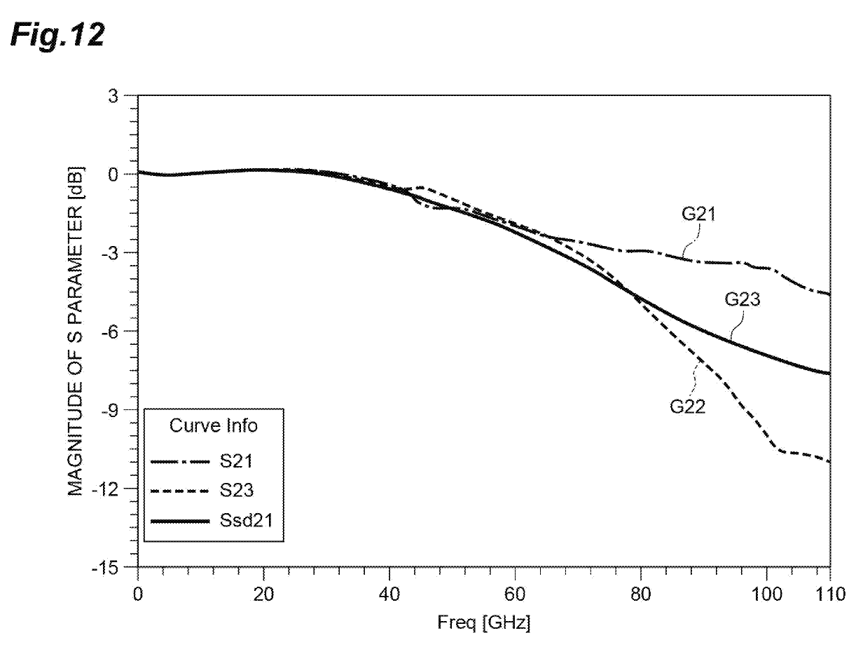

FIGS. 11 and 12 are graphs showing the frequency characteristics of S parameters of the optical modulator 3. The horizontal axis indicates a frequency (GHz), and the vertical axis indicates the magnitude (dB) of the S parameters. Curves G11 and G21 show the frequency characteristics of transmission on the non-inverting side (S21 parameter), curves G12 and G22 show the frequency characteristics of transmission on the inverting side (S23 parameter), and curves G13 and G23 show the frequency characteristics of differential transmission (Ssd21 parameter). FIG. 11 shows a case where the third region 51c of the contact layer 51 is electrically connected to the second region 51b, unlike in the present embodiment. FIG. 12 shows a case where the third region 51c of the contact layer 51 is electrically isolated from the second region 51b, as in the present embodiment. Referring to FIGS. 11 and 12, compared with the case where the third region 51c is electrically connected to the second region 51b, in the case where the third region 51c is electrically isolated from the second region 51b, all of the S21 parameter, the S23 parameter, and the Ssd21 parameter are improved in the high frequency band. From this, it can be seen that parasitic capacitance is reduced by electrically isolating the third region 51c from the second region 51b and accordingly, the high-frequency characteristics of the optical modulator 3 can be improved.

As in the present embodiment, in the optical modulator 3, in addition to the first region 51a, the second region 51b, the third region 51c, and the fourth region 51d, the region 62 where the contact layer 51 has not been removed may be present. In this case, the time required to remove the contact layer 51 can be shortened by reducing the area of the region 61 where the contact layer 51 is to be removed.

As in the present embodiment, the region 61 where the contact layer 51 has been removed may be a region where the recess 50 penetrating the embedding region 82 and the contact layer 51 is formed. In this case, partial removal of the contact layer 51 on the substrate 2 can be easily performed.

As in the present embodiment, the region 61 where the contact layer 51 has been removed may reach the light emission end surface 1a. In this case, the first region 51a is interposed between the regions 61 where the contact layer 51 has been removed, up to the light emission end surface 1a. As a result, since the parasitic capacitance generated between the first region 51a of the contact layer 51 and the base is further reduced, it is possible to further improve the high-frequency characteristics of the optical modulator 3.

As in the present embodiment, the first region 51a may include the portion 51a1 including the light emission end surface 1a and a remaining portion located on a side opposite to the light emission end surface 1a with respect to the portion 51a1. Then, the width W1 of the portion 51a1 in the lateral direction may be greater than the width of the remaining portion in the lateral direction. In this case, since the width of the portion interposed between the recesses 50 increases at the light emission end surface 1a, the mechanical strength of the portion interposed between the recesses 50 increases, making it easier to cleave the light emission end surface 1a.

The optical modulator integrated laser device 1 according to the present embodiment includes the optical modulator 3 and the laser section 4 that is provided on the substrate 2 and outputs laser light. The optical modulator 3 receives the laser light from the laser section 4. According to the optical modulator integrated laser device 1, since the optical modulator 3 is included, the parasitic capacitance generated between the contact layer 51 and the base can be reduced, thereby improving the high-frequency characteristics.

### First Modification

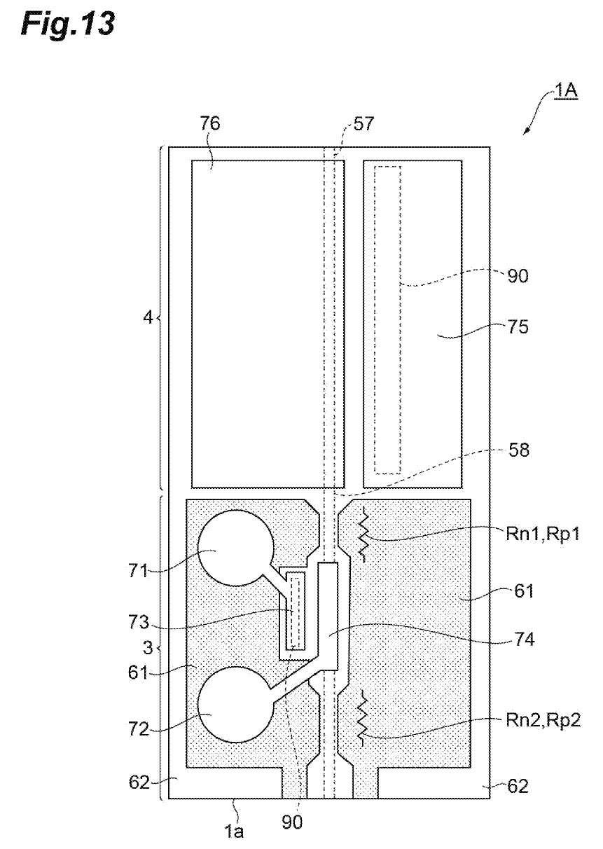

FIG. 13 is a plan view showing an optical modulator integrated laser device 1A according to a first Modification. The optical modulator integrated laser device 1A according to this Modification is different from the above embodiment in the shapes of the regions 61 and 62, but is the same as the above embodiment in other respects.

In this Modification, the region 62 of the optical modulator 3 is provided along the peripheral edge portion of the substrate 2 and is connected to the region 62 of the laser section 4. In addition, the region 61 is formed in a wide region adjacent to the mesa structure 58. Then, the recess 50 is formed below the first electrode pad 71 and below the second electrode pad 72. That is, the first electrode pad 71 and the second electrode pad 72 are formed in the region 61. Specifically, the first electrode pad 71 and the second electrode pad 72 are provided on the substrate 2 exposed from the contact layer 51 with the insulating film 81 interposed therebetween. Therefore, in this Modification, the contact layer 51 does not have the third region 51c and the fourth region 51d.

Even in a configuration such as that of this Modification, the same effects as in the above embodiment can be obtained. In addition, by providing the region 62 along the peripheral edge portion of the substrate 2 as in this Modification, cutting during singulation of the optical modulator integrated laser device can be facilitated.

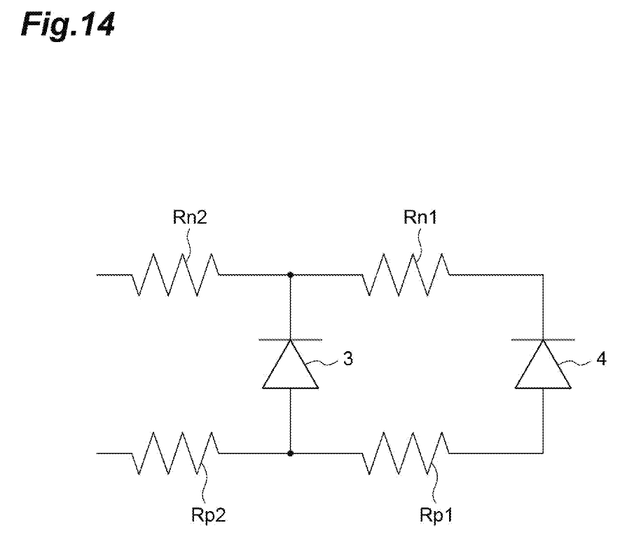

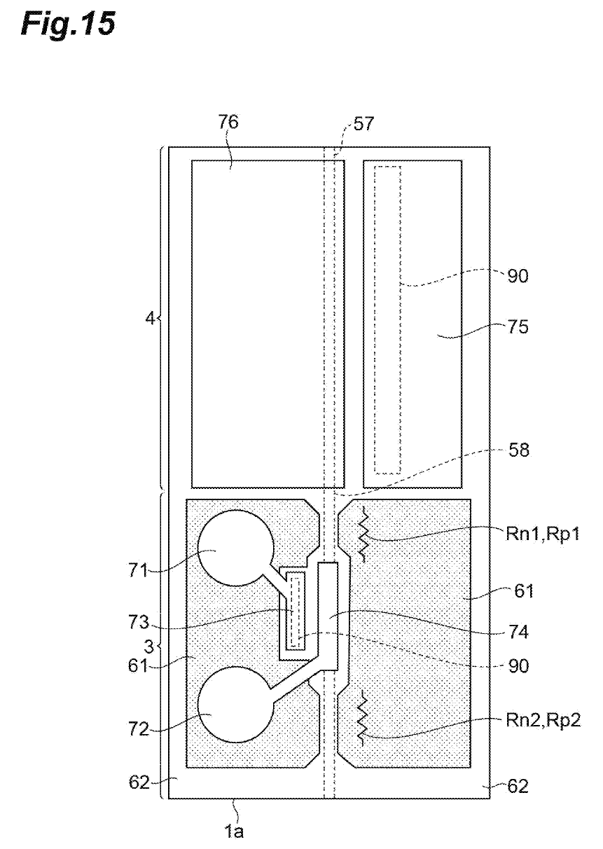

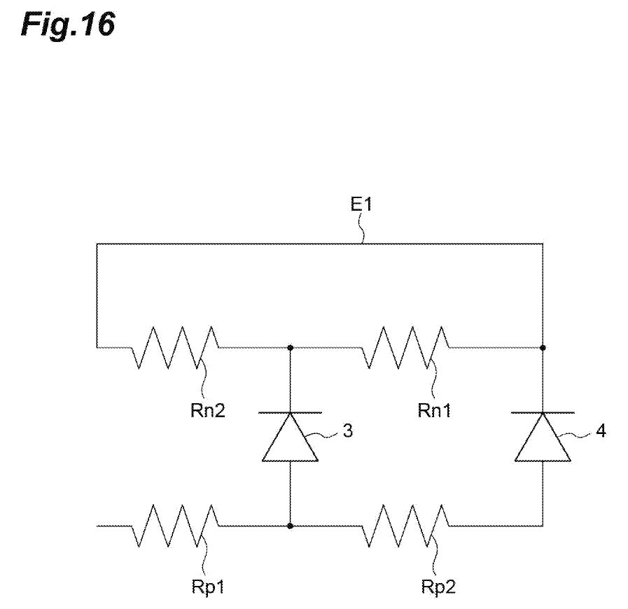

Furthermore, in this Modification, as in the above embodiment, the region 61 where the contact layer 51 has been removed reaches the light emission end surface 1a. Here, FIG. 14 is a circuit diagram showing a case where the region 61 reaches the light emission end surface 1a as in this Modification. FIG. 15 is a plan view showing a configuration in which the region 61 does not reach the light emission end surface 1a, which is different from this Modification, and FIG. 16 is a circuit diagram showing this case. In FIGS. 14 and 16, the optical modulator 3 and the laser section 4 are simply represented by diode symbols, the cathode of the optical modulator 3 and the cathode of the laser section 4 are connected to each other through an isolation resistor Rn1, and the anode of the optical modulator 3 and the anode of the laser section 4 are connected to each other through an isolation resistor Rp1. In addition, a tip-side isolation resistor Rn2 extends from the cathode of the optical modulator 3 toward the light emission end surface 1a, and a tip-side isolation resistor Rp2 extends from the anode of the optical modulator 3 toward the light emission end surface 1a. The isolation resistors Rn1 and Rp1 and the tip-side isolation resistors Rn2 and Rp2 are also schematically shown in FIGS. 13 and 15.

When the region 61 does not reach the light emission end surface 1a as shown in FIG. 15, the cathode of the optical modulator 3 and the cathode of the laser section 4 are connected to each other through a conductive path E1 formed at the peripheral edge portion, as shown in FIG. 16. As a result, the isolation resistance between the optical modulator 3 and the laser section 4 decreases. In contrast, when the region 61 reaches the light emission end surface 1a as shown in FIG. 13, the cathode of the optical modulator 3 and the cathode of the laser section 4 are not connected to each other through the conductive path formed in the peripheral edge portion, as shown in FIG. 14. As a result, the isolation resistance between the optical modulator 3 and the laser section 4 can be increased. Therefore, it is possible to reduce interference of the drive signal input to the optical modulator 3 with a bias voltage input to the laser section 4.

### Second Modification

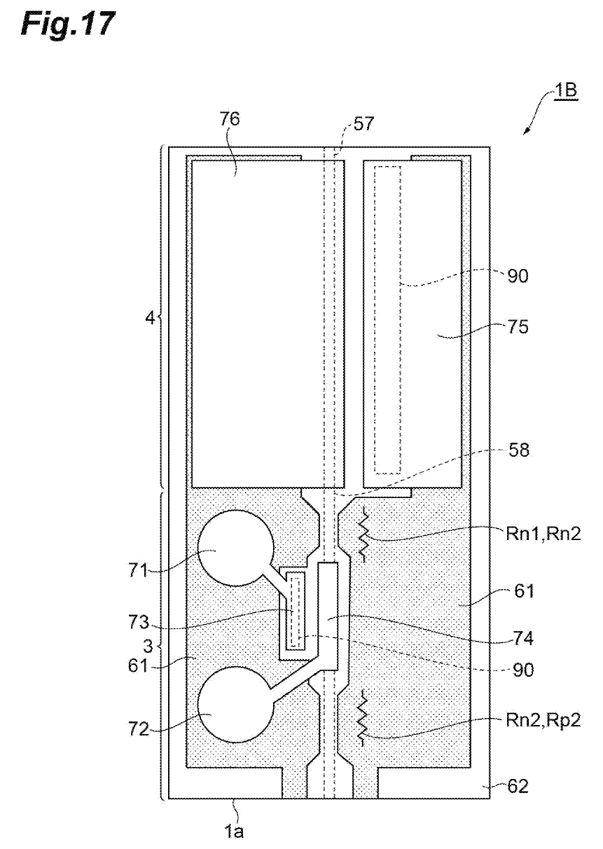

FIG. 17 is a plan view showing an optical modulator integrated laser device 1B according to a second Modification. The optical modulator integrated laser device 1B according to this Modification is different from the above embodiment in that the region 61 where the contact layer 51 has been removed is also provided in the laser section 4, but is the same as the above embodiment in other respects.

In this Modification, the recess 50 is formed in a region excluding the peripheral edge portion of the substrate 2, and this region is defined as the region 61 where the contact layer 51 has been removed. The region 61 is formed in a wide region adjacent to the mesa structure 57. Then, the recess 50 is formed below the electrode pad 75 and below the electrode pad 76. That is, the electrode pad 75 and the electrode pad 76 are formed in the region 61. Specifically, the electrode pad 75 and the electrode pad 76 are provided on the substrate 2 exposed from the contact layer 51 with the insulating film 81 interposed therebetween.

As in this Modification, the region 61 where the contact layer 51 has been removed may be provided in the laser section 4. Then, the contact layer 51 may be partially removed on the substrate 2 of the laser section 4. In this case, parasitic capacitance generated between the contact layer 51 and the base can also be reduced in the laser section 4. Therefore, parasitic capacitance generated between the contact layer 51 and the base can be further reduced, thereby further improving the high-frequency characteristics of the optical modulator 3.

### Third Modification

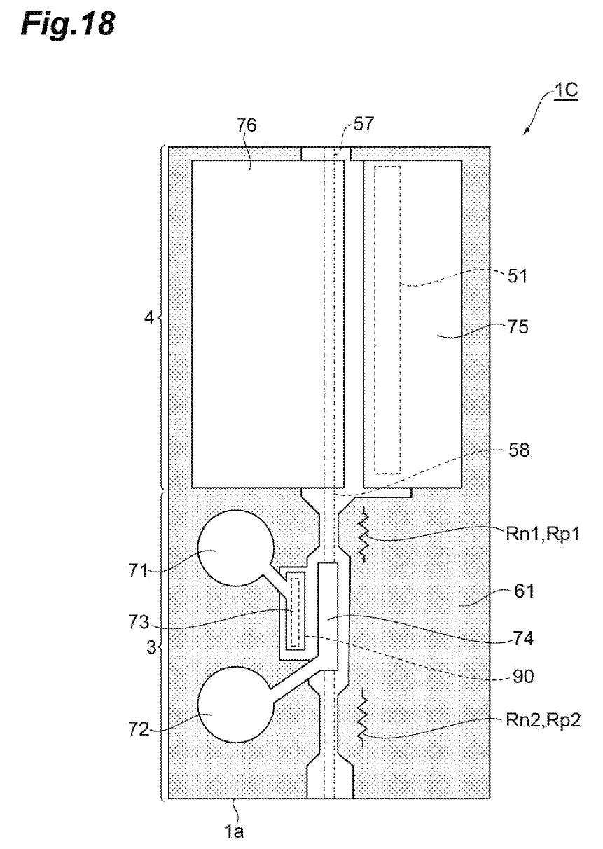

FIG. 18 is a plan view showing an optical modulator integrated laser device 1C according to a third Modification. The optical modulator integrated laser device 1C according to this Modification is different from the above embodiment in the shapes of the regions 61 and 62, but is the same as the above embodiment in other respects.

In this Modification, in the optical modulator 3, the contact layer 51 is removed in all regions excluding the first region 51a and the second region 51b. That is, the recess 50 is formed in all regions excluding the first region 51a and the second region 51b, and these regions are defined as the region 61. According to this Modification, since the parasitic capacitance generated between the first region 51a and the second region 51b of the contact layer 51 and the base is further reduced, it is possible to further improve the high-frequency characteristics of the optical modulator 3. As shown in FIG. 18, in the laser section 4 as well, the contact layer 51 may be removed in all regions excluding a region located between the mesa structure 57 and the substrate 2 and a peripheral region thereof.

### Fourth Modification

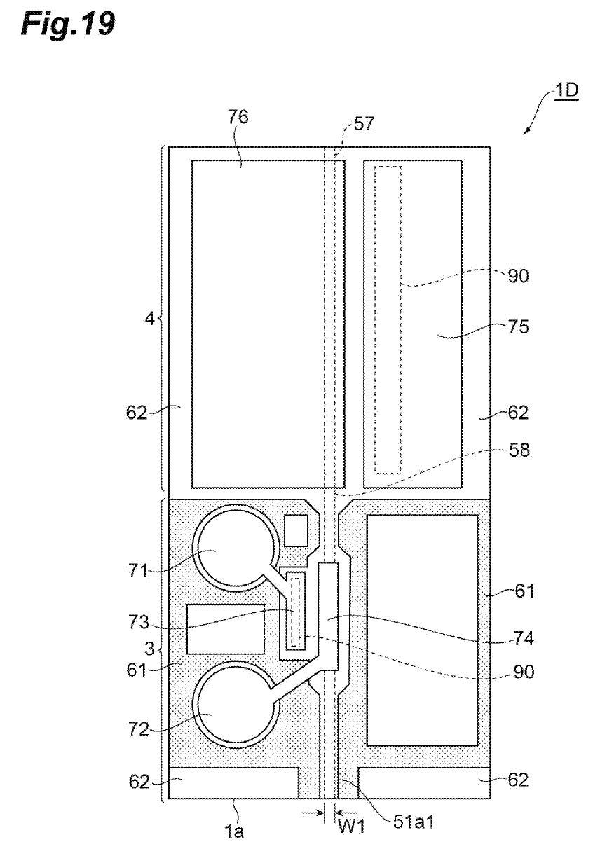

FIG. 19 is a plan view showing an optical modulator integrated laser device 1D according to a fourth Modification. In the optical modulator integrated laser device 1D according to this Modification, the width W1 of the portion 51a1 (first portion) including the light emission end surface 1a in the lateral direction is equal to or smaller than the width of the remaining portion in the lateral direction. Even with such a configuration, the same effects as in the above embodiment can be obtained.

### Fifth Modification

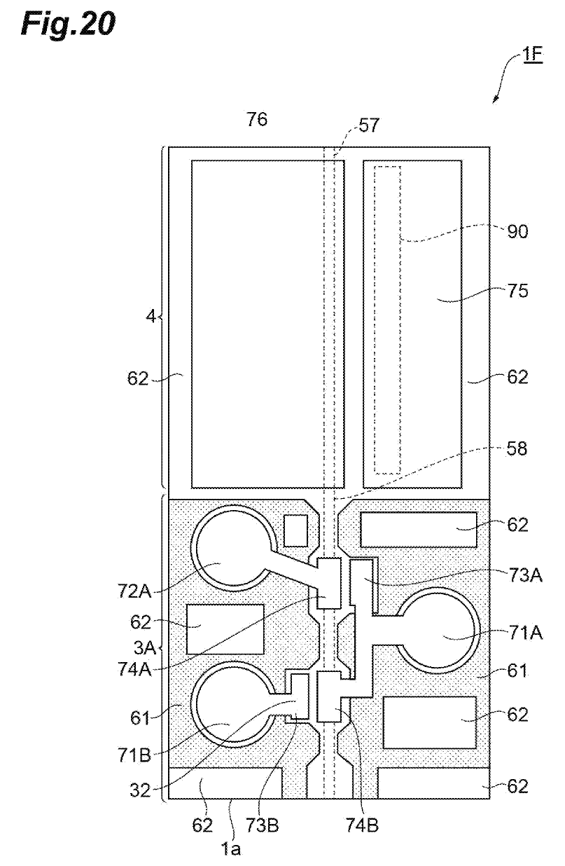

FIG. 20 is a plan view showing an optical modulator integrated laser device 1F according to a fifth Modification. The optical modulator integrated laser device 1F according to this Modification is different from the above embodiment in that the optical modulator integrated laser device 1F includes an optical modulator 3A instead of the optical modulator 3, but is the same as the above embodiment in other respects. The optical modulator 3A includes a first optical modulator 31 and a second optical modulator 32 that are optically coupled in series. Therefore, the optical modulator 3A has electrode pads 71A, 71B, and 72A and wirings 73A, 73B, 74A, and 74B instead of the first electrode pad 71, the second electrode pad 72, the wiring 73, and the wiring 74 in the above embodiment.

The electrode pad 72A is an electrode pad belonging to the first optical modulator 31. The electrode pad 71B is an electrode pad belonging to the second optical modulator 32. The electrode pad 71A is an electrode pad belonging to both the first optical modulator 31 and the second optical modulator 32. In the first optical modulator 31, the electrode pad 71A corresponds to the first electrode pad, and the electrode pad 72A corresponds to the second electrode pad. In the second optical modulator 32, the electrode pad 71B corresponds to the first electrode pad, and the electrode pad 71A corresponds to the second electrode pad.

The electrode pads 71A, 71B, and 72A and the wirings 73A, 73B, 74A, and 74B are metal films, and are gold (Au) films in one example. The electrode pads 71A, 71B, and 72A are provided above the embedding region 82 and on the insulating film 81. As shown in FIG. 20, the electrode pad 71A is arranged on one side of the mesa structure 58. The electrode pads 71B and 72A are arranged on the other side of the mesa structure 58. The planar shapes of the electrode pads 71A, 71B, and 72A are, for example, circular.

The wirings 73A and 74A are wirings belonging to the first optical modulator 31. The wiring 73A electrically connects the electrode pad 71A and the contact layer 51 of the first optical modulator 31 to each other. The wiring 73A includes a portion, which is provided on the second region 51b of the contact layer 51 to make ohmic contact with the second region 51b, and a portion connected to the electrode pad 71A. The wiring 74A electrically connects the electrode pad 72A and the second cladding layer 54 of the first optical modulator 31 to each other.

The wirings 73B and 74B are wirings belonging to the second optical modulator 32. The wiring 73B electrically connects the electrode pad 71B and the contact layer 51 of the second optical modulator 32 to each other. The wiring 73B includes a portion, which is provided on the second region 51b of the contact layer 51 to make ohmic contact with the second region 51b, and a portion connected to the electrode pad 71B. The wiring 74B electrically connects the electrode pad 71A and the second cladding layer 54 of the second optical modulator 32 to each other.

Even when the optical modulator 3A includes the first optical modulator 31 and the second optical modulator 32 as in this Modification, the same effects as in the above embodiment can be obtained by partially removing the contact layer 51 on the substrate 2.

### Sixth Modification

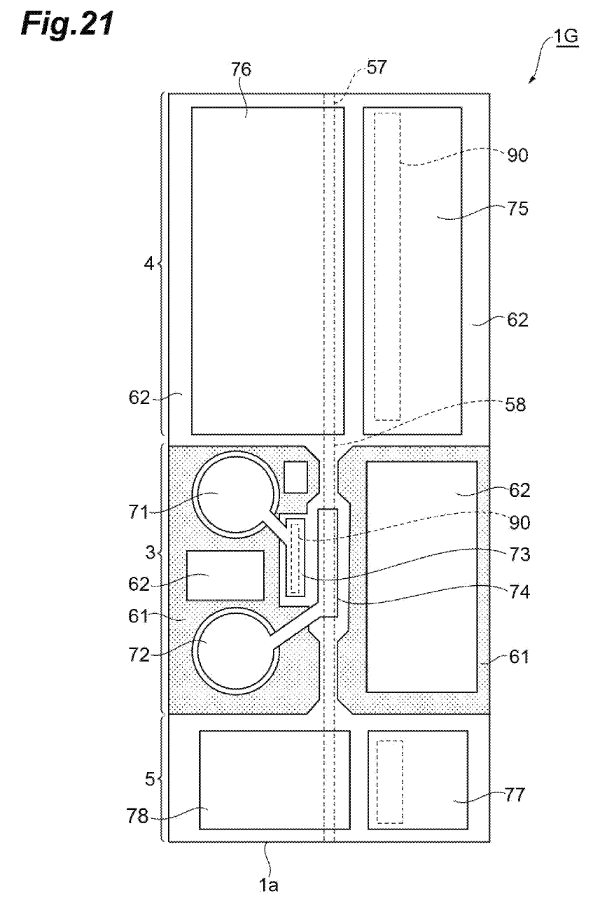

FIG. 21 is a plan view showing an optical modulator integrated laser device 1G according to a sixth Modification. The optical modulator integrated laser device 1G further includes a semiconductor optical amplifier (SOA) 5 in addition to the same configuration as the optical modulator integrated laser device 1 according to the above embodiment. The semiconductor optical amplifier 5 is monolithically provided on the same substrate 2 as the optical modulator 3 and the laser section 4. The semiconductor optical amplifier 5 is provided on a side opposite to the laser section 4 with respect to the optical modulator 3, and is adjacent to the optical modulator 3 in the optical waveguide direction D1. The semiconductor optical amplifier 5 receives modulated laser light from the optical modulator 3, amplifies and outputs the modulated laser light. The semiconductor optical amplifier 5 has an electrode pad 77 that makes ohmic contact with the contact layer 51 and an electrode pad 78 that makes ohmic contact with the second cladding layer 54. In this Modification as well, since the contact layer 51 of the optical modulator 3 is partially removed on the substrate 2, the same effects as those of the above embodiment can be obtained. In addition, since the semiconductor optical amplifier 5 is provided on the same substrate 2 as the optical modulator 3 and the laser section 4, the optical modulator integrated laser device 1G including the semiconductor optical amplifier 5 can be made smaller. The semiconductor optical amplifier 5 may also be provided in the first to fifth Modifications described above.

### Seventh Modification

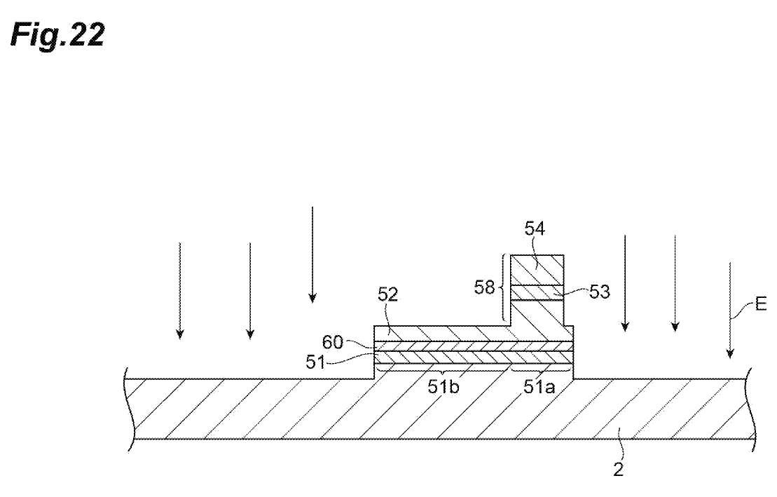

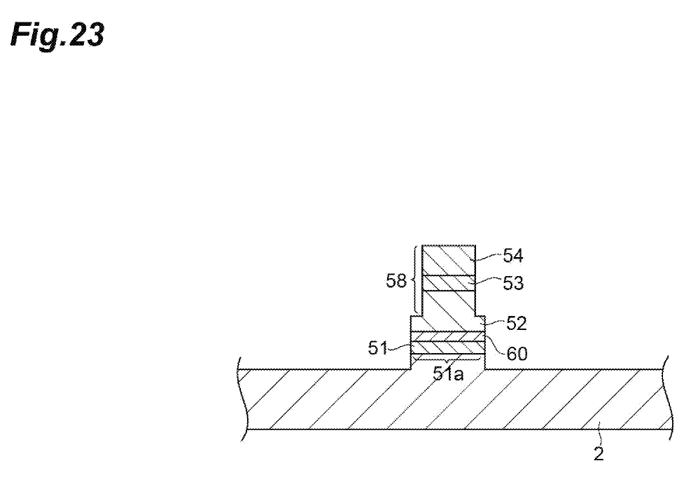

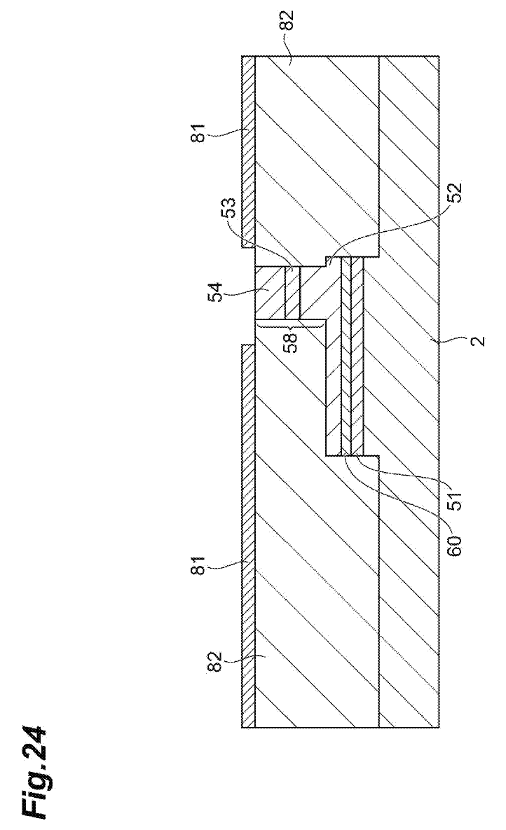

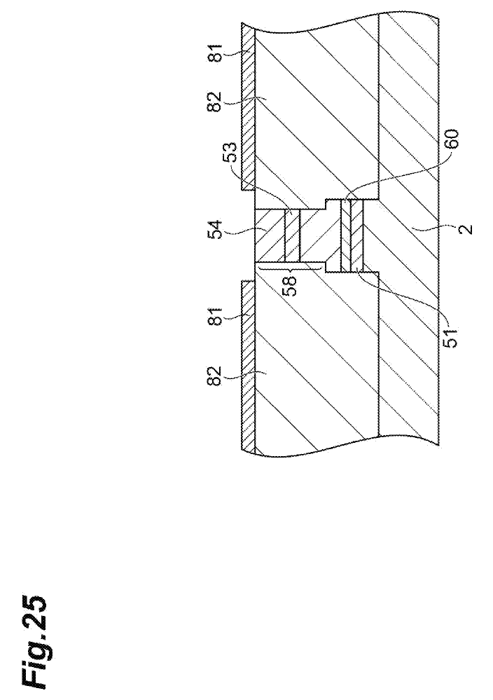

FIGS. 22-25 are drawings for explaining another structural example of the region 61 where the contact layer 51 has been removed. In this example, first, as shown in FIGS. 22 and 23, etching (for example, dry etching, indicated by arrow E in the drawings) is performed around the first region 51a and the second region 51b of the contact layer 51 to remove the contact layer 51 around the first region 51a and the second region 51b. Then, as shown in FIGS. 24 and 25, the embedding region 82 is deposited in the etched region, and the insulating film 81 is formed on the embedding region 82. FIGS. 22 and 24 show the optical modulator 3 and the laser section 4, and FIGS. 23 and 25 show a portion between the optical modulator 3 and the laser section 4. Even with the structure of this Modification, it is possible to obtain the region 61 where the contact layer 51 has been removed. In addition, according to this Modification, the unevenness of the surface of the optical modulator integrated laser device can be reduced, thereby facilitating processes such as forming wirings on the surface.

### Eighth Modification

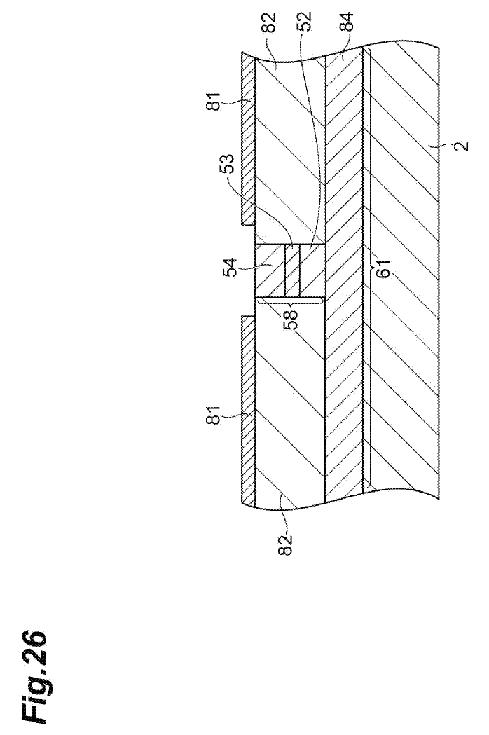

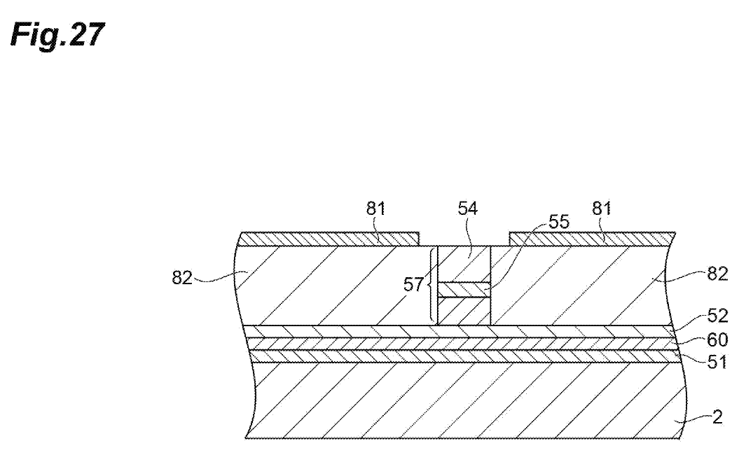

FIGS. 26 and 27 are drawings for explaining still another structural example of the region 61 where the contact layer 51 has been removed. FIG. 26 is a drawing schematically showing a cross section of the region 61 where the contact layer 51 has been removed. FIG. 27 is a drawing schematically showing a cross section of the laser section 4 that does not include the region 61, for comparison. As shown in FIG. 26, in the region 61, an insulating or semi-insulating layer 84 may be provided in place of the contact layer 51. Even with such a configuration, the same effects as those of the above embodiment can be obtained.

The optical modulator and the optical modulator integrated laser device according to the present disclosure are not limited to the embodiment and its Modifications described above, and various other modifications are possible. For example, in the embodiment and its Modifications described above, an optical modulator integrated laser device that monolithically includes an optical modulator and a laser section has been exemplified, but the configuration of the present disclosure can also be applied to a device that does not include a laser section and only includes an optical modulator. The structure of the region where the contact layer has been removed is not limited to the embodiment and its Modifications described above. In the embodiment and its Modifications described above, the case where the electrode-connection semiconductor layer is a contact layer has been exemplified, but the electrode-connection semiconductor layer may include a part of the first cladding layer 52, or may be formed by only a part of the first cladding layer 52. In this case, in the embodiment and its Modifications described above, the contact layer is to be read as an electrode-connection semiconductor layer. In the embodiment and its Modifications described above, the case where the first conductivity type is n-type and the second conductivity type is p-type has been exemplified, but the first conductivity type may be p-type and the second conductivity type may be n-type.

What is claimed is:

1. An electro-absorption modulator, comprising:
a semi-insulating or insulating substrate;
a first cladding layer of a first conductivity type provided on the substrate;
a light absorption layer provided on the first cladding layer;
a second cladding layer of a second conductivity type provided on the light absorption layer; and
a contact layer of the first conductivity type including a part of the first cladding layer or provided between the substrate and the first cladding layer,
wherein the first cladding layer, the light absorption layer, and the second cladding layer form a mesa structure extending in an optical waveguide direction,
the contact layer includes:
a first region including a region located between the mesa structure and the substrate; and
a second region exposed from the first cladding layer for electrical connection,
the contact layer is partially removed on the substrate, and
the first region and the second region are interposed between regions where the contact layer has been removed.

2. The electro-absorption modulator according to claim 1, further comprising:
a first electrode pad electrically connected to the contact layer; and
a second electrode pad electrically connected to the second cladding layer,
wherein the contact layer further includes a third region located between the first electrode pad and the substrate and a fourth region located between the second electrode pad and the substrate, and
the third region and the fourth region are electrically isolated from the first region and the second region by the regions where the contact layer has been removed.

3. The electro-absorption modulator according to claim 2,
wherein, in addition to the first region, the second region, the third region, and the fourth region, a region where the contact layer has not been removed is present.

4. The electro-absorption modulator according to claim 1,
wherein the contact layer is removed in all regions excluding the first region and the second region.

5. The electro-absorption modulator according to claim 1,
wherein the regions where the contact layer has been removed reach a light emission end surface.

6. The electro-absorption modulator according to claim 1, further comprising:
a semi-insulating or insulating embedding region that embeds both sides of the mesa structure,
wherein the regions where the contact layer has been removed are regions where a recess penetrating the embedding region and the contact layer is formed.

7. The electro-absorption modulator according to claim 6,
wherein the first region includes a first portion including a light emission end surface and a second portion located on a side opposite to the light emission end surface with respect to the first portion, and
a width of the first portion in a direction perpendicular to the optical waveguide direction is greater than a width of the second portion in the direction perpendicular to the optical waveguide direction.

8. The electro-absorption modulator according to claim 1,
wherein the electro-absorption modulator includes a first optical modulator and a second optical modulator.

9. An optical modulator integrated laser device, comprising:
an optical modulator section that is the electro-absorption modulator according to claim 1; and
a laser section that is provided on the substrate and outputs laser light,
wherein the optical modulator section receives the laser light from the laser section.

10. The optical modulator integrated laser device according to claim 9,
wherein the contact layer is partially removed on the substrate in the laser section.

11. The optical modulator integrated laser device according to claim 9, further comprising:
a semiconductor optical amplifier provided on a light emission end surface side of the optical modulator section,
wherein the semiconductor optical amplifier receives the laser light after modulation from the optical modulator section, amplifies and outputs the modulated laser light.

12. The optical modulator integrated laser device according to claim 11,
wherein the semiconductor optical amplifier is provided on the substrate.
